(19) United States
(12) Patent Application Publication
(10) Pub. No.: US 2009/0096087 A1
(43) Pub. Date: Apr. 16, 2009

(54) MICROELECTRONIC ASSEMBLY AND METHOD OF PREPARING SAME

(76) Inventors: Ioan Sauciuc, Phoenix, AZ (US); Kazimierz L. Kozyra, Olympia, WA (US); Sandeep Ahuja, University Place, WA (US); Gregory M. Chrysler, Chandler, AZ (US)

Correspondence Address: INTEL CORPORATION;c/o CPA Global, P.O. BOX 52050, MINNEAPOLIS, MN, 55402, US

(21) Appl. No.: 11/872,056

(22) Filed: Oct. 15, 2007

(51) Int. Cl. H01L 23/36; H01L 21/58

(52) U.S. Cl. 257/717; 438/123; 257/E21.505; 257/E23.101

(57) ABSTRACT

A microelectronic assembly includes a die (110, 210) having a surface (111, 211), a heat sink (120, 220) removably attached to the die, a thermally conductive layer (130, 230) between the die and the heat sink, and an anti-adhesion layer (140, 240) between the die and the heat sink. The thermally conductive layer conforms to a contour of the surface of the die.

### FIELD OF THE INVENTION

The disclosed embodiments of the invention relate generally to thermal management of microelectronic devices, and relate more particularly to a re-workable thermal solution that conforms to the shape of individual dies.

### BACKGROUND OF THE INVENTION

Microelectronic devices are typically housed in packages that can be mounted to a circuit board or the like and integrated into a microelectronic system. The design of a microelectronic device must address both mechanical attachment and heat dissipation in order to maximize thermal performance and ease of assembly, including component replacement, when necessary.

### BRIEF DESCRIPTION OF THE DRAWINGS

The disclosed embodiments will be better understood from a reading of the following detailed description, taken in conjunction with the accompanying figures in the drawings in which:

FIG. 1 is a cross-sectional view of a microelectronic assembly according to an embodiment of the invention;

FIG. 2 is a cross-sectional view of a microelectronic assembly according to another embodiment of the invention;

FIG. 3 is a flowchart illustrating a method of preparing a microelectronic assembly according to an embodiment of the invention; and

FIG. 4 is a chart illustrating junction temperatures for various thermal management options according to embodiments of the invention as compared to a typical microelectronic package having an integrated heat spreader.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

### DETAILED DESCRIPTION OF THE DRAWINGS

In one embodiment of the invention, a microelectronic assembly comprises a die having a surface, a heat sink removably attached to the die, a thermally conductive layer between the die and the heat sink, and an anti-adhesion layer between the die and the heat sink. The thermally conductive layer conforms to a contour of the surface of the die.

A variety of factors may be of importance in order to maintain good thermal performance for a bare die at low cost. For example: (1) the thermal interface layer should conform to the die warpage and roughness; (2) the thermal interface material (TIM) layer should be very thin and/or very highly thermally conductive; and (3) the heat sink should not be permanently attached to the die. The first factor may be achieved by melting certain solder material after the heat sink has been attached to the die. The second and third factors may be achieved by applying an anti-adhesion layer to the die, thus ensuring that the solder material will not adhere to the die so as to enable easy separation of heat sink and die such that component replacement may be accomplished. A goal is to achieve good thermal contact and low strength mechanical contact so that the heat sink and the die can be separated easily without damaging the die (whether for the convenience of an original equipment manufacturer (OEM) or other reasons).

Embodiments of the invention make use of two thermal interfaces: a high conductivity solder and a thin layer of an agent that prevents solder adhesion to the die (the anti-adhesion layer). If pressure is applied during soldering the solder layer will be permanently attached to the heat sink only and at the same time will mirror the shape of the die. The anti-adhesion layer will be maintained between the solder and the die (at least in some embodiments, but see below for other possible configurations) and will also prevent the permanent attachment of the heat sink to the die.

Many existing microelectronic packages may include an integrated heat spreader (IHS). Although an IHS provides a thermal benefit by distributing the heat flux from a small heat source area to a larger area it can also somewhat inhibit heat transfer because it represents an additional interface across which the heat flux must travel. An IHS is also included in some microelectronic packages for mechanical purposes, e.g., to provide support and stability to a microelectronic package and also to provide a flat surface for the attachment of addition components. Embodiments of the invention allow for the production of bare die packages that have no IHS and that do not suffer from a deterioration in thermal performance. The elimination of an IHS may represent a cost reduction opportunity.

Embodiments of the invention may reduce or eliminate damage to the C4 (controlled collapse chip connect) bump interface during shock and vibration, may lower adoption costs for users of microelectronic packages compared to packages employing a permanent soldering attachment, may enable central processing unit (CPU) or other component exchange due to the removable thermal solution, and/or may result in good thermal performance for the bare die CPU comparable to the IHS performance.

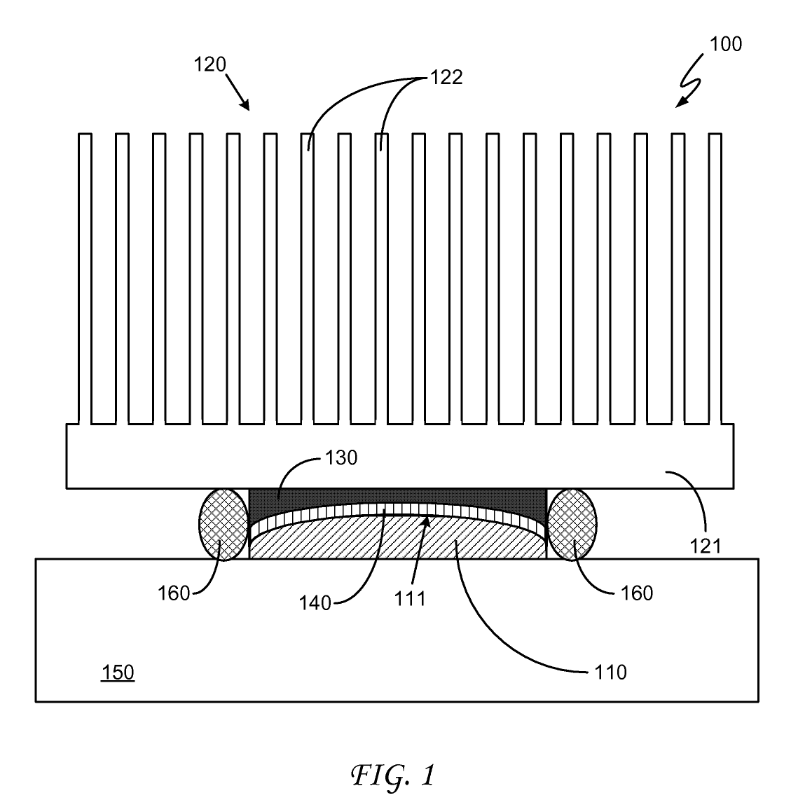

Referring now to the drawings, FIG. 1 is a cross-sectional view of a microelectronic assembly 100 according to an embodiment of the invention. As illustrated in FIG. 1, microelectronic assembly 100 comprises a die 110 having a surface 111, a heat sink 120 removably attached to die 110, a thermally conductive layer 130 between die 110 and heat sink 120, and an anti-adhesion layer 140 between die 110 and heat sink 120. Heat sink 120 comprises a heat sink base 121 and fins 122 attached to and extending away from heat sink base 121. Die 110 is depicted as resting on a substrate 150, which may be a motherboard or other system board, a carrier, or the like. C4 bumps or other attachment mechanisms joining die 110 to substrate 150 are not illustrated. In other non-illustrated embodiments, die 110 could be attached to a cold plate, a heat slug, a heat pipe, a vapor chamber, or the like rather than to a heat sink.

The surfaces of microelectronic dies may appear to be flat but in reality are often warped to some degree. If this warpage is not compensated for it can lead to air gaps between the die and a component resting on the die. Because air is a poor conductor of heat, these air gaps tend to interfere with thermal management efforts for the die and can result in unwanted reductions in performance of and/or damage to the die. As illustrated in FIG. 1, and as explained elsewhere herein, thermally conductive layer 130 conforms to the non-linear (warped) contour of surface 111 of die 110.

In one embodiment, thermally conductive layer 130 comprises a solder or other meltable metal material. As an example, the meltable metal can have a melting point between approximately zero degrees Celsius and approximately 220 degrees Celsius. As another example, thermally conductive layer 130 comprises one or more of gallium, indium, tin, and bismuth, either individually, as an alloy with another material or materials, or in combination with one or more of the other listed elements. For a particular embodiment of the invention, examples of possible compositions for thermally conductive layer 130, listed in order of preference beginning with the most preferred composition, include: tin-bismuth; indium-tin-bismuth; indium alone; and gallium-indium-tin. Tin-bismuth, for example, is very inexpensive and has a melting point similar to indium, which is widely used in existing soldering applications. It should be noted here that in other embodiments, different compositions may be more preferred and/or a different order of preference may apply.

According to one embodiment, anti-adhesion layer 140 comprises a layer of oil. As an example, the oil can be a high-grade transformer oil, a poly-a-olefin oil, glycerin, or the like. In a different embodiment, anti-adhesion layer 140 comprises a layer of wax. Beeswax is one type of wax that may be used. Another is candelilla wax, derived from the leaves of the candelilla shrub that is found in northern Mexico and the southwestern United States. Candelilla wax has a relatively high thermal conductivity of approximately 2 watts per meter-kelvin (W/m·K), making it one of the best waxes (if not the very best) for use in anti-adhesion layer 140. Whatever its composition, anti-adhesion layer 140 should be thermally conductive.

Anti-adhesion layer 140 should, in certain embodiments, be as thin as possible. Grease, which contains tiny metal particles on the order of 20-40 micrometers, cannot be compressed below these values. Oil, on the other hand, contains no particles and can thus be squeezed into a layer of appropriate thickness. Accordingly, in order that anti-adhesion layer 140 can be compressed easily, it may be said that it should contain no particles or other fillers (although in some embodiments fillers or particles may be present as long as adequate compressibility is possible).

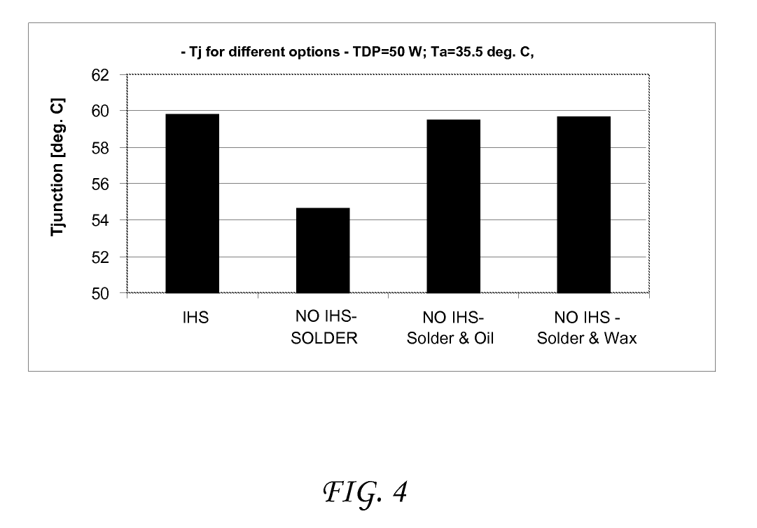

In one embodiment, anti-adhesion layer 140 has a thickness between approximately 2 micrometers and approximately 25 micrometers. Thicknesses in this range tend to allow heat to pass easily across the layer so that it can be dissipated. It should be understood, however, that thicker anti-adhesion layers can also be used, possibly in connection with materials of higher thermal conductivity. In fact, the thickness and/or the thermal conductivity of anti-adhesion layer 140 can be varied, the latter by a selection of material having the desired thermal properties, in order to arrive at a desired junction temperature anywhere within a range of values, as further discussed below in connection with FIG. 4.

Illustrated in FIG. 1 is an embodiment of the invention in which anti-adhesion layer 140 is between thermally conductive layer 130 and die 110. In a non-illustrated embodiment, anti-adhesion layer 140 is between thermally conductive layer 130 and heat sink 120 and thermally conductively layer 130 is permanently attached to die 110. Another non-illustrated embodiment comprises two anti-adhesion layers, one of which is between thermally conductive layer 130 and die 110 and the other of which is between thermally conductive layer 130 and heat sink 120. All of these embodiments achieve a purpose of embodiments of the invention: the enablement of an ability to remove die 110 from heat sink 120 without damaging either component.

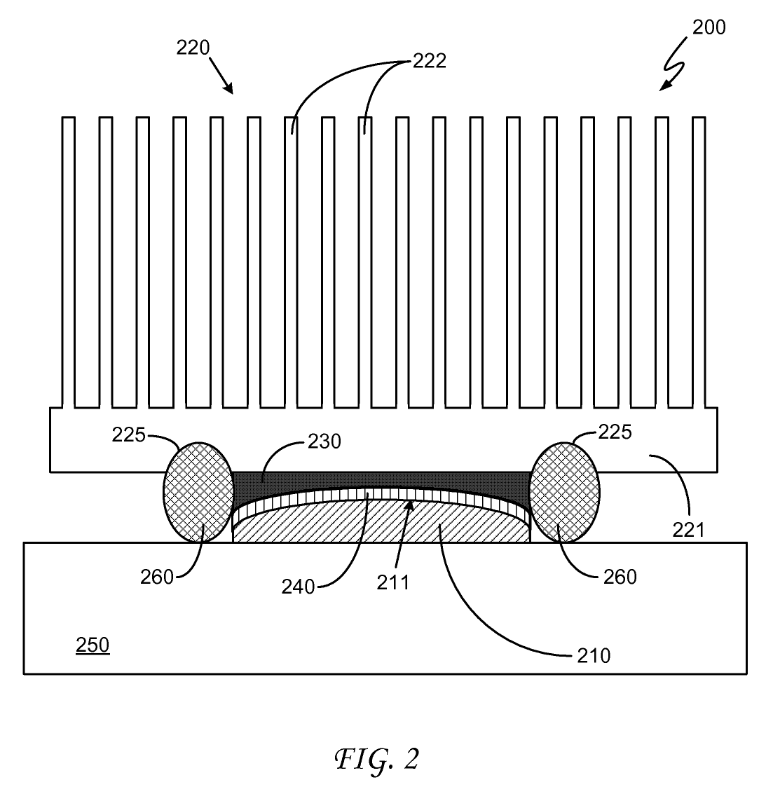

In the illustrated embodiment, microelectronic assembly 100 further comprises a gasket 160 around die 110. Gasket 160 operates to prevent solder pump-out or squeeze-out during manufacture of microelectronic assembly 100. As an example, gasket 160 can be made of rubber or some other compressible material. Gasket 160 can be removed after fabrication of microelectronic assembly 100 or it may be left in place. In some embodiments no gasket is used at all. In another embodiment the gasket may be contained within an indentation in the heat sink base, as illustrated in FIG. 2. It should be understood that the two features of FIG. 1 that are identified as gasket 160 are two portions of a single gasket that forms a ring around die 110. Because these are seen in cross section they appear to be separate components, but such is not the case.

FIG. 2 is a cross-sectional view of a microelectronic assembly 200 according to an embodiment of the invention. As illustrated in FIG. 2, microelectronic assembly 200 comprises a die 210 having a surface 211, a heat sink 220 removably attached to die 210, a thermally conductive layer 230 between die 210 and heat sink 220, and an anti-adhesion layer 240 between die 210 and heat sink 220. Heat sink 220 comprises a heat sink base 221 and fins 222 attached to and extending away from heat sink base 221. Die 210 is depicted as resting on a substrate 250. (C4 bumps or other attachment mechanisms joining die 210 to substrate 250 are not illustrated.) A gasket 260 at least partially surrounds die 210. As an example, die 210, surface 211, heat sink 220, thermally conductive layer 230, anti-adhesion layer 240, heat sink base 221, fins 222, substrate 250, and gasket 260 can be similar to, respectively, die 110, surface 111, heat sink 120, thermally conductive layer 130, anti-adhesion layer 140, heat sink base 121, fins 122, substrate 150, and gasket 160, all of which are shown in FIG. 1.

Heat sink base 221 contains an indentation 225 in which gasket 260 is at least partially contained. FIG. 2 shows gasket 260 as entirely filling indentation 225. In a different embodiment there may be a gap between indentation 225 and gasket 260. Other embodiments, like that shown in FIG. 1, that have no indentation may hold the gasket in place using a compression fit, a retention arm, or the like.

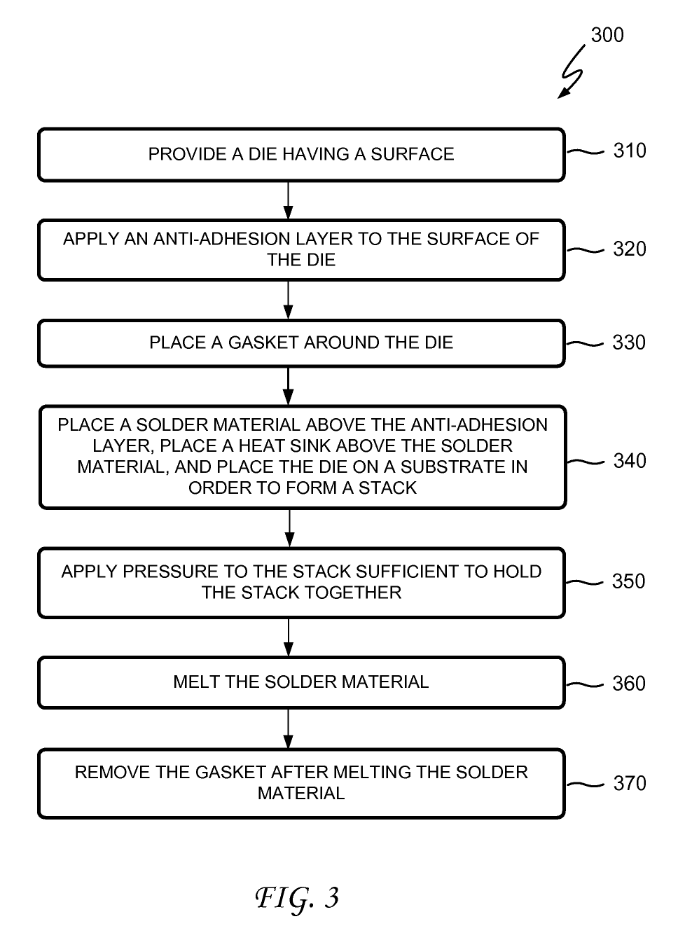

FIG. 3 is a flowchart illustrating a method 300 of preparing a microelectronic assembly according to an embodiment of the invention. A step 310 of method 300 is to provide a die having a surface. As an example, the die can be similar to die 110 and the surface can be similar to surface 111, both of which are shown in FIG. 1.

A step 320 of method 300 is to apply an anti-adhesion layer to the surface of the die. As an example, the anti-adhesion layer can be similar to anti-adhesion layer 140 that is shown in FIG. 1.

A step 330 of method 300 is to place a gasket around the die. As an example, the gasket can be similar to gasket 160 that is shown in FIG. 1. In one embodiment, step 330 comprises placing the gasket in an indentation, similar to indentation 225 (see FIG. 2) within the base of the heat sink.

A step 340 of method 300 is to place a solder material above the anti-adhesion layer, place a heat sink above the solder material, and place the die on a substrate in order to form a stack. As an example, the solder material, the heat sink, and the substrate can be similar to, respectively, thermally conductive layer 130, heat sink 120, and substrate 150, all of which are shown in FIG. 1. (It should be understood that in many embodiments the die and the substrate are already formed into a single unit before the attachment of the heat sink takes place.)

A step 350 of method 300 is to apply pressure to the stack sufficient to hold the stack together. In one embodiment, such pressure may be applied using a retention mechanism—a clamp, a clip, a retention band, or the like, to hold the components of the stack together. In other embodiments the pressure may be applied is other ways, including applying the required pressure by hand.

A step 360 of method 300 is to melt the solder material. In one embodiment, the solder material is a rectangular (or other) solder foil that is permanently attached only to the base of the heat sink (and not to the die), and step 360 comprises reflowing the solder foil in a reflow oven. A possible disadvantage of this embodiment is that it subjects the microelectronic assembly to elevated temperatures (perhaps as high as approximately 110 degrees Celsius) that could potentially be damaging to some component or components. Because of the pressure being exerted on the stack (see step 350), the melted solder will take the shape of the die. If the die is warped, the solder will follow the warped contour of the die. The presence of the anti-adhesion layer will prevent a permanent attachment to the die.

In another embodiment, the solder material is a reactive multilayer solder foil, as described below, and step 360 comprises igniting the reactive multilayer solder foil. As has been described above, igniting the reactive multilayer solder foil occurs, or can be made to occur, in such a way that the anti-adhesion layer, the heat sink, the die, and the substrate are not significantly heated. According to at least some embodiments, step 360 is performed during the performance of step 350 such that pressure is applied to the melting solder. In some embodiments this will ensure that the anti-adhesion layer is sufficiently thin.

The reactive multilayer solder foil embodiment proposes to use a soldering material and process to locally melt the solder without the need to use a reflow the oven. One solder that is suitable for this embodiment is proprietary to the Reactive Nanotechnologies (RNT) company of Hunt Valley, Md., USA. An advantage of the local melting process is that it takes just milliseconds to melt the solder—a short enough time that the other board/die components will not be significantly heated. As an example, the solder foil is ignited and heat diffuses along, and is contained within, certain layers of the solder foil. During this process the solder will melt and take the shape of the die due to the pressure exercised by the retention mechanism (see step 350).

A step 370 of method 300 is to remove the gasket after melting the solder material. As discussed above, step 370 is optional, and in some embodiments the gasket, if it is present, will be left in place around the die even after the solder material is melted and assembly is complete.

FIG. 4 is a chart illustrating junction temperature (Tⱼ) for various thermal management options according to embodiments of the invention as compared to a typical microelectronic package having an IHS as known in the art. As may be seen, the depicted comparison options according to embodiments of the invention are: (1) solder with no anti-adhesion layer; (2) solder plus an oil anti-adhesion layer; and (3) solder plus a wax anti-adhesion layer. The physical attributes of the heat sink, including material properties, dimensions, fin area, overall volume, etc., are assumed to be constant for each option, as are the thermal boundary conditions.

The following table sets forth boundary conditions applicable to FIG. 4. In the table, TIM 2=the second thermal interface material—that between the IHS and the heat sink, K=thermal conductivity, and BLT=bond line thickness (the thickness of the anti-adhesion layer). In FIG. 4, TDR=thermal design power, and Tₐ=ambient temperature.

| | | No IHS/ | No IHS/ | No IHS/Solder |
|---|---|---|---|---|
| | IHS | Solder | Solder & Oil | & Wax |
| K TIM2 [W/m · K] | 4 | N/A | N/A | N/A |
| BLT TIM2 [μm] | 200 | N/A | N/A | N/A |
| K Solder [W/m · K] | 30.9 | 30.9 | 30.9 | 30.9 |
| BLT Solder [μm] | 200 | 200 | 198 | 177 |
| K Oil/Wax [W/m · K] | N/A | N/A | 0.18 | 2 |
| BLT Oil/Wax [μm] | N/A | N/A | 2 | 23 |

FIG. 4 illustrates that, given boundary conditions as set forth in the table, the temperature of a junction with a solder layer but without an anti-adhesion layer is slightly more than 54 degrees Celsius, while the temperatures of junctions having a solder layer and an oil or a wax anti-adhesion layer are approximately 59 degrees Celsius. It should be noted, however, that, as mentioned above, the BLT and the thermal conductivity of the anti-adhesion layer can be adjusted such that the junction temperature can be caused to fall anywhere in the range between approximately 54 degrees and 60 degrees Celsius. Other temperature ranges may be achievable under other boundary conditions and/or when using other anti-adhesion layer materials. Lower temperatures, of course, are preferred but must be balanced again cost and other factors.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the microelectronic assemblies and related methods discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A microelectronic assembly comprising:
a die having a surface;
a heat sink removably attached to the die;
a thermally conductive layer between the die and the heat sink, the thermally conductive layer conforming to a contour of the surface of the die; and
an anti-adhesion layer between the die and the heat sink.

2. The microelectronic assembly of claim 1 wherein:
the thermally conductive layer comprises a meltable metal having a melting point between approximately zero degrees Celsius and approximately 220 degrees Celsius.

3. The microelectronic assembly of claim 1 wherein:
the thermally conductive layer comprises one or more of gallium, indium, tin, and bismuth.

4. The microelectronic assembly of claim 1 wherein:
the anti-adhesion layer comprises a layer of oil.

5. The microelectronic assembly of claim 1 wherein:
the anti-adhesion layer comprises a layer of wax.

6. The microelectronic assembly of claim 1 wherein:
the anti-adhesion layer is between the thermally conductive layer and the die.

7. The microelectronic assembly of claim 1 wherein:
the anti-adhesion layer is between the thermally conductive layer and the heat sink.

8. The microelectronic assembly of claim 1 wherein:
the anti-adhesion layer has a thickness between approximately 2 micrometers and approximately 25 micrometers.

9. The microelectronic assembly of claim 1 further comprising:
a gasket around the die.

10. The microelectronic assembly of claim 9 wherein:
the heat sink has a base containing an indentation; and
the gasket is at least partially contained within the indentation.

11. A method of preparing a microelectronic assembly, the method comprising:
providing a die having a surface;
applying an anti-adhesion layer to the surface of the die;
placing a solder material above the anti-adhesion layer, placing a heat sink above the solder material, and placing the die on a substrate in order to form a stack;
applying pressure to the stack sufficient to hold the stack together; and
melting the solder material.

12. The method of claim 11 wherein:
the solder material is a solder foil; and
melting the solder comprises reflowing the solder foil in a reflow oven.

13. The method of claim 11 wherein:
the solder material is a reactive multilayer solder foil; and
melting the solder comprises igniting the reactive multilayer solder foil.

14. The method of claim 11 further comprising:
placing a gasket around the die.

15. The method of claim 14 further comprising:
removing the gasket after melting the solder material.
